(19) United States
(12) Patent Application Publication
(10) Pub. No.: US 2009/0289740 A1
(43) Pub. Date: Nov. 26, 2009

(54) ACOUSTIC WAVE FILTER APPARATUS AND DUPLEXER

(75) Inventor: Yuichi Takamine, Ishikawa-gun (JP)

Correspondence Address: MURATA MANUFACTURING COMPANY, LTD.;C/O KEATING & BENNETT, LLP, 1800 Alexander Bell Drive, SUITE 200, Reston, VA, 20191, US

(73) Assignee: MURATA MANUFACTURING CO., LTD., Nagaokakyo-shi (JP)

(21) Appl. No.: 12/539,875

(22) Filed: Aug. 12, 2009

Related U.S. Application Data
(63) Continuation of application No. PCT/JP2008/050697, filed on Jan. 21, 2008.

(30) Foreign Application Priority Data
Mar. 1, 2007 (JP) 2007-051686

(51) Int. Cl. H03H 9/205

(52) U.S. Cl. 333/132; 333/195

(57) ABSTRACT

A second band pass filter that is used in a filter device, which has a relatively high pass band, in the pass band of a first band pass filter is provided. One end of a second IDT of a second longitudinally coupled resonator surface acoustic wave filter portion is connected to a first balanced terminal and the other end thereof is connected to a second balanced terminal. Each of a first longitudinally coupled resonator surface acoustic wave filter portion and the second longitudinally coupled resonator surface acoustic wave filter portion has narrow pitch electrode finger portions. The number of electrode fingers of the narrow pitch electrode finger portion of the second IDT of the first longitudinally coupled resonator surface acoustic wave filter portion is greater than the number of electrode fingers of the narrow pitch electrode finger portion of the second IDT of the second longitudinally coupled resonator surface acoustic wave filter portion.

### BACKGROUND OF THE INVENTION

1. Field of the Invention

The present invention relates to an acoustic wave filter apparatus that is used, for example, in an RF duplexer of a mobile phone. In particular, the present invention relates to an acoustic wave filter apparatus that has a balanced/unbalanced conversion function and is used as one of two filters that has a pass band at a high frequency side in the duplexer. In addition, the present invention relates to a duplexer that includes such an acoustic wave filter apparatus.

2. Description of the Related Art

In the field of mobile phones, there is a demand for a component that has a plurality of functions so as to reduce the number of components in the mobile phones. As an example of a component that provides a plurality of functions, various duplexers that are provided with a transmission-side band pass filter and a reception-side band pass filter have been proposed.

For example, a duplexer that is schematically illustrated in a plan view in FIG. 11 is disclosed in Japanese Unexamined Patent Application Publication No. H10-341135. A duplexer 1001 includes a piezoelectric substrate 1002. An electrode structure that is schematically illustrated in FIG. 11 is provided on the piezoelectric substrate 1002 so as to define a transmission-side band pass filter 1004 and a reception-side band pass filter 1005. The pass band of the reception-side band pass filter 1005 has a higher frequency than the pass band of the transmission-side band pass filter 1004.

The reception-side band pass filter 1005 is connected to a common terminal 1003, which is connected to an antenna, through surface acoustic wave resonators 1006 and 1007. The reception-side band pass filter 1005 is a three IDT-type longitudinally coupled resonator surface acoustic wave filter. The reception-side band pass filter 1005 includes a first IDT 1005a, a second IDT 1005b, and a third IDT 1005c arranged in sequence along a surface acoustic wave propagation direction. One end of the second IDT 1005b is connected to a first balanced terminal 1008. The other end of the second IDT 1005b is connected to a second balanced terminal 1009. That is, the reception-side band pass filter 1005 is a float-balance type longitudinally coupled resonator surface acoustic wave filter having a balanced/unbalanced conversion function.

The transmission-side band pass filter 1004 includes a first IDT 1004a, a second IDT 1004b, and a third IDT 1004c. The second IDT 1004b, which is provided at the middle portion thereof, is connected to the common terminal 1003 through a surface acoustic wave resonator 1010. One end of the first IDT 1004a and one end of the third IDT 1004c are connected in common to a transmission terminal 1011. Each of a plurality of terminals excluding the common terminal 1003, the first balanced terminal 1008, the second balanced terminal 1009, and the transmission terminal 1011 is connected to a ground potential. For example, a terminal 1013 is connected to a ground potential.

In the duplexer 1001, the impedance should be high in the transmission-side band pass filter 1004 in the pass band of the reception-side band pass filter 1005. Ideally, the impedance should be infinite. Similarly, the impedance should be high in the reception-side band pass filter 1005 in the pass band of the transmission-side band pass filter 1004. Ideally, the impedance should be infinite.

For this reason, the one-port surface acoustic wave resonators 1006 and 1007 are provided between the reception-side band pass filter 1005 and the common terminal 1003. With the one-port surface acoustic wave resonators 1006 and 1007 being connected between the reception-side band pass filter 1005 and the common terminal 1003, it is possible to increase the impedance of the reception-side band pass filter 1005 in the pass band of the transmission-side band pass filter 1004.

In the description of this specification, the increasing of the impedance of one band pass filter, such as the transmission-side band pass filter or the reception-side band pass filter, explained above in the pass band of the other band pass filter is referred to as “phase adjustment” wherever appropriate.

In a configuration in which the surface acoustic wave resonators 1006 and 1007 are connected between the reception-side band pass filter 1005, that is, a longitudinally coupled resonator surface acoustic wave filter, and the common terminal 1003, which is connected to the antenna, as described in the Japanese Unexamined Patent Application Publication No. H10-341135, a problem arises in that the insertion loss of the reception-side band pass filter 1005 increases due to the insertion of the surface acoustic wave resonators 1006 and 1007.

As an alternative method for making phase adjustments, specifically, as another method for increasing the impedance of the reception-side band pass filter 1005 in the pass band of the transmission-side band pass filter 1004, there is a method of reducing the number of electrode finger pairs of the first IDT 1005a and the third IDT 1005c. That is, a method of reducing the number of electrode finger pairs of the IDT 1005a and the IDT 1005c, each of which is an IDT that is connected to the terminal of the antenna, is known as such an alternative method.

FIGS. 12A and 12B are a set of impedance Smith charts that illustrate the results of phase adjustment when the number of electrode finger pairs of the IDTs 1005a and 1005c is reduced. FIG. 12A is an impedance Smith chart that shows pre-phase-adjustment characteristics. FIG. 12B is an impedance Smith chart that shows the results of phase adjustment when the number of electrode finger pairs of each of the first IDT 1005a and the third IDT 1005c is reduced by subtracting five pairs therefrom.

Note that the characteristics illustrated in FIGS. 12A and 12B are an example of characteristics obtained when an EGSM reception filter is defined by the reception-side band pass filter 1005.

A marker A is shown in FIGS. 12A and 12B. The marker A indicates the position of the center frequency of the EGSM transmission frequency band, which is 897.5 MHz. In comparison with the characteristics shown in FIG. 12B, it is understood that the impedance at the frequency of 897.5 MHz in the characteristics shown in FIG. 12B is shifted to a higher impedance side.

However, if the method of reducing the number of electrode finger pairs of the first IDT 1005a and the third IDT 1005c is used, a resistance value in the pass band of the transmission-side band pass filter 1004 in the reception-side band pass filter 1005 increases. For this reason, a problem arises in that the insertion loss of the transmission-side band pass filter 1004 worsens when the duplexer 1001 is configured.

### SUMMARY OF THE INVENTION

To overcome the problems described above, preferred embodiments of the present invention provide an acoustic wave filter apparatus that has a balanced/unbalanced conversion function and is used as a second band pass filter of a duplexer that includes a first band pass filter having a pass band at a relatively low frequency side and the second band pass filter having a pass band at a relatively high frequency side. When the duplexer is configured, the acoustic wave filter apparatus is capable of increasing the impedance of the second band pass filter in the pass band of the first band pass filter without causing an increase in the insertion loss of the first band pass filter. Preferred embodiments of the present invention further provide a duplexer that includes an acoustic wave filter apparatus as the second band pass filter thereof.

A preferred embodiment of the present invention provides an acoustic wave filter apparatus that has a balanced/unbalanced conversion function and is used as a second band pass filter of an acoustic wave filter device that includes a first band pass filter having a pass band at a relatively low frequency side and the second band pass filter having a pass band at a relatively high frequency side, one end of the first band pass filter and one end of the second band pass filter being connected to a common terminal, the acoustic wave filter apparatus including a piezoelectric substrate, and a first longitudinally coupled resonator acoustic wave filter portion and a second longitudinally coupled resonator acoustic wave filter portion that are provided on the piezoelectric substrate, wherein each of the first longitudinally coupled resonator acoustic wave filter portion and the second longitudinally coupled resonator acoustic wave filter portion includes a first IDT, a second IDT, and a third IDT arranged in sequence along a propagation direction of an acoustic wave, one end of the first IDT of the first longitudinally coupled resonator acoustic wave filter portion and one end of the first IDT of the second longitudinally coupled resonator acoustic wave filter portion are connected to each other, and in addition thereto, one end of the third IDT of the first longitudinally coupled resonator acoustic wave filter portion and one end of the third IDT of the second longitudinally coupled resonator acoustic wave filter portion are connected to each other so that the first longitudinally coupled resonator acoustic wave filter portion and the second longitudinally coupled resonator acoustic wave filter portion are cascade-connected, an end of the second IDT of the first longitudinally coupled resonator acoustic wave filter portion is connected to the common terminal, one end of the second IDT of the second longitudinally coupled resonator acoustic wave filter portion is connected to a first balanced terminal whereas the other end of the second IDT of the second longitudinally coupled resonator acoustic wave filter portion is connected to a second balanced terminal, each of the first longitudinally coupled resonator acoustic wave filter portion and the second longitudinally coupled resonator acoustic wave filter portion has a narrow pitch electrode finger portion that is provided at a gap-facing portion in a pair of the IDTs that are arranged adjacent to each other with a gap therebetween when viewed in the acoustic wave propagation direction, a pitch of electrode fingers of the narrow pitch electrode finger portion is less than a pitch of electrode fingers of an IDT portion excluding the narrow pitch electrode finger portion, and the number of the electrode fingers of the narrow pitch electrode finger portion of the second IDT of the first longitudinally coupled resonator acoustic wave filter portion is greater than the number of the electrode fingers of the narrow pitch electrode finger portion of the second IDT of the second longitudinally coupled resonator acoustic wave filter portion.

Preferably, an acoustic wave filter apparatus includes a plurality of acoustic wave filter apparatuses according to a preferred embodiment of the present invention, wherein the plurality of acoustic wave filter apparatuses are connected to one another in parallel. With such a preferred configuration, since the plurality of acoustic wave filter apparatuses are connected in parallel, the insertion loss of the second band pass filter can be further reduced.

In an acoustic wave filter apparatus according to a preferred embodiment of the present invention, a surface acoustic wave may preferably be used as an acoustic wave. In this manner, it is possible to provide a surface acoustic wave filter apparatus according to a preferred embodiment of the present invention that is capable of increasing the impedance of the second band pass filter in the pass band of the first band pass filter without causing an increase in the insertion loss of the first band pass filter.

In an acoustic wave filter apparatus according to a preferred embodiment of the present invention, a boundary acoustic wave may be used as an acoustic wave. In this manner, it is possible to provide a boundary acoustic wave filter apparatus that is capable of increasing impedance of the second band pass filter in the pass band of the first band pass filter without causing an increase in the insertion loss of the first band pass filter.

A duplexer according to a preferred embodiment of the present invention includes a first band pass filter having a relatively low frequency pass band and a second band pass filter having a relatively high frequency pass band. One end of the first band pass filter of the duplexer and one end of the second band pass filter thereof are connected to a common terminal. In addition, the second band pass filter of the duplexer is an acoustic wave filter apparatus according to a preferred embodiment of the present invention. Therefore, it is possible to provide a duplexer that is capable of increasing impedance in the second band pass filter in the pass band of the first band pass filter without causing an increase in the insertion loss of the first band pass filter and the second band pass filter and thus, provides excellent filter characteristics.

An acoustic wave filter apparatus according to a preferred embodiment of the present invention is a float-balance type acoustic wave filter portion including a first longitudinally coupled resonator acoustic wave filter portion and a second longitudinally coupled resonator acoustic wave filter portion that are cascade-connected in which an end of a second IDT of the first longitudinally coupled resonator acoustic wave filter portion is connected to a common terminal, which defines an unbalanced terminal, one end of the second IDT of the second longitudinally coupled resonator acoustic wave filter portion is connected to a first balanced terminal whereas the other end of the second IDT of the second longitudinally coupled resonator acoustic wave filter portion is connected to a second balanced terminal. In such a configuration, the number of electrode fingers of a narrow pitch electrode finger portion of the second IDT of the first longitudinally coupled resonator acoustic wave filter portion is greater than the number of electrode fingers of a narrow pitch electrode finger portion of the second IDT of the second longitudinally coupled resonator acoustic wave filter portion. Accordingly, the number of electrode fingers of the IDT connected to the common terminal is greater than that of a neutral-point type longitudinally coupled resonator acoustic wave filter having a balanced/unbalanced conversion function. Therefore, it is possible to increase the resistance in the pass band of the first band pass filter in the second band pass filter, which makes it possible to, in the second band pass filter, increase the impedance in the pass band of the first band pass filter without causing an increase in insertion loss.

Thus, preferred embodiments of the present invention makes it possible to increase the impedance in the second band pass filter in the pass band of the first band pass filter without causing an increase in insertion loss. That is, preferred embodiments of the present invention enable phase adjustment. In addition, the design of the acoustic wave filter can be simplified because the surface acoustic wave resonators 1006 and 1007 illustrated in FIG. 11 can be omitted.

Other features, elements, steps, characteristics and advantages of the present invention will become more apparent from the following detailed description of preferred embodiments of the present invention with reference to the attached drawings.

### BRIEF DESCRIPTION OF THE DRAWINGS

FIG. 1 is a plan view that schematically illustrates a duplexer according to a preferred embodiment of the present invention.

FIG. 2 is a plan view that schematically illustrates narrow pitch electrode finger portions that are provided in IDTs in the preferred embodiment of the present invention illustrated in FIG. 1.

FIG. 3 is a diagram that shows the transmission characteristics of a reception-side band pass filter in a duplexer according to a preferred embodiment of the present invention and the transmission characteristics of a reception-side band pass filter in a duplexer according to a comparative example.

FIG. 4 is a diagram that shows the transmission characteristics of a transmission-side band pass filter in a duplexer according to a preferred embodiment of the present invention and the transmission characteristics of a transmission-side band pass filter in a duplexer according to a comparative example.

FIG. 5 is a diagram that shows the transmission characteristics of each of a transmission-side band pass filter according to a preferred embodiment of the present invention and a transmission-side band pass filter according to a comparative example that are obtained when loss caused by impedance mismatching in the transmission-side band pass filter is eliminated through calculation.

FIG. 6 is a plan view that schematically illustrates a surface acoustic wave filter apparatus prepared as a comparative example.

FIGS. 7A and 7B are impedance Smith charts for a reception-side band pass filter in a duplexer according to a preferred embodiment of the present invention and for a reception-side band pass filter in a duplexer according to a comparative example, respectively.

FIG. 8 is a plan view that schematically illustrates a duplexer according to a modified example of the preferred embodiment of the present invention illustrated in FIG. 1.

FIG. 9 is a plan view that schematically illustrates a duplexer according to another modified example of the preferred embodiment of the present invention illustrated in FIG. 1.

FIG. 10 is a front-elevation sectional view that schematically illustrates an example of a boundary acoustic wave filter apparatus.

FIG. 11 is a plan view that schematically illustrates an example of a duplexer of the prior art.

FIG. 12A is a diagram that shows an impedance Smith chart for a reception-side band pass filter in a duplexer of prior art and FIG. 12B is a diagram that shows an impedance Smith chart obtained when the number of electrode finger pairs of each of IDTs connected to a common terminal is made less than that of FIG. 12A by subtracting five pairs therefrom.

### DETAILED DESCRIPTION OF PREFERRED EMBODIMENTS

With reference to the accompanying drawings, preferred embodiments of the present invention will be described.

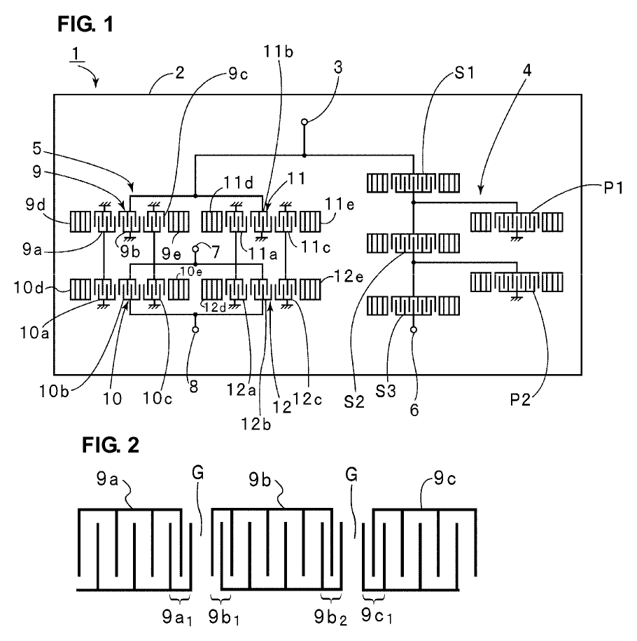

FIG. 1 is a plan view that schematically illustrates a duplexer according to a first preferred embodiment of the present invention.

A duplexer 1 is provided with a piezoelectric substrate 2. The piezoelectric substrate 2 according to the present preferred embodiment of the present invention is preferably made of 42° Y-cut X-propagation LiTaO3, for example. The piezoelectric substrate 2 may preferably be made of LiTaO3 with other cut angles, or the piezoelectric substrate 2 may preferably be made of other piezoelectric single crystal, such as LiNbO₃ or may be made of piezoelectric ceramics, for example.

An electrode structure illustrated in FIG. 1 is arranged on the piezoelectric substrate 2 so as to define the duplexer 1. In the present preferred embodiment, Al is preferably used as an electrode material that forms the electrode structure, for example. Notwithstanding the above, Cu or Au may preferably be used as the electrode material, for example, or an alloy may preferably be used as the electrode material, for example. As another example, electrodes may preferably be defined by a lamination of a plurality of metal films.

The duplexer 1 according to the present preferred embodiment is preferably an EGSM duplexer, for example. The EGSM transmission frequency band ranges from about 880 MHz to about 915 MHz. The EGSM reception frequency band ranges from about 925 MHz to about 960 MHz.

The duplexer 1 includes a common terminal 3, which defines an unbalanced terminal. A transmission-side band pass filter 4 and a reception-side band pass filter 5 are connected to the common terminal 3. The transmission-side band pass filter 4 is an example of a first band pass filter. The reception-side band pass filter 5 is an example of a second band pass filter.

The transmission-side band pass filter 4 includes a transmission terminal 6. A signal that is to be transmitted is inputted to the transmission terminal 6. The signal is sent to the common terminal 3, which is connected to an antenna. The transmission-side band pass filter 4 is preferably a ladder filter that includes a plurality of serial arm resonators S1, S2, and S3 and a plurality of parallel arm resonators P1 and P2, for example. Each of the serial arm resonators S1, S2, and S3 and the parallel arm resonators P1 and P2 described herein is preferably defined by a single port type surface acoustic wave resonator. That is, the transmission-side band pass filter 4 is a ladder type surface acoustic wave filter apparatus.

On the other hand, the reception-side band pass filter 5 is provided with a first balanced terminal 7 and a second balanced terminal 8. By providing the common terminal 3 that defines an unbalanced terminal and with the first balanced terminal 7 and the second balanced terminal 8, the reception-side band pass filter 5 functions as a band pass filter (BPF) that has a balanced/unbalanced conversion function. The impedance of the common terminal 3 is preferably about 50Ω, or example. The impedance of the first balanced terminal 7 and the second balanced terminal 8 is preferably about 100Ω, for example. In the present preferred embodiment, a circuit that includes a first longitudinally coupled resonator surface acoustic wave filter portion 9 and a second longitudinally coupled resonator surface acoustic wave filter portion 10 that are cascade-connected and another circuit that includes another first longitudinally coupled resonator surface acoustic wave filter portion 11 and another second longitudinally coupled resonator surface acoustic wave filter portion 12 that are cascade-connected are connected to the common terminal 3.

The first longitudinally coupled resonator surface acoustic wave filter portion 9 includes three IDTs, that is, a first IDT 9a, a second IDT 9b, and a third IDT 9c, which are arranged in a surface acoustic wave propagation direction. The first longitudinally coupled resonator surface acoustic wave filter portion 11 also includes three IDTs, that is, a first IDT 11a, a second IDT 11b, and a third IDT 11c, which are arranged in the surface acoustic wave propagation direction. A reflector 9d is provided adjacent to one side of an area in which the first IDT 9a, the second IDT 9b, and the third IDT 9c are provided when viewed in the surface acoustic wave propagation direction. Another reflector 9e is provided adjacent to the other opposite side of the area in which the IDTs 9a, 9b, and 9c are provided when viewed in the surface acoustic wave propagation direction. In a similar manner, the first longitudinally coupled resonator surface acoustic wave filter portion 11 is provided with reflectors 11d and 11e.

One end of the second IDT 9b of the first longitudinally coupled resonator surface acoustic wave filter portion 9 and one end of the second IDT 11b of the first longitudinally coupled resonator surface acoustic wave filter portion 11 are connected in common to the common terminal 3. Each of the other end of the second IDT 9b and the other end of the second IDT 11b is connected to a ground potential.

Each of the second longitudinally coupled resonator surface acoustic wave filter portions 10 and 12 is also a three IDT-type longitudinally coupled resonator surface acoustic wave filter. The second longitudinally coupled resonator surface acoustic wave filter portion 10 includes a first IDT 10a, a second IDT 10b, and a third IDT 10c arranged in sequence along the surface acoustic wave propagation direction. The second longitudinally coupled resonator surface acoustic wave filter portion 12 includes a first IDT 12a, a second IDT 12b, and a third IDT 12c arranged in sequence along the surface acoustic wave propagation direction. As in the configuration of the first longitudinally coupled resonator surface acoustic wave filter portion, the second longitudinally coupled resonator surface acoustic wave filter portion 10 includes reflectors 10d and 10e that are adjacent to the respective sides of an IDT area when viewed in the surface acoustic wave propagation direction. The second longitudinally coupled resonator surface acoustic wave filter portion 12 also includes reflectors 12d and 12e that are adjacent to the respective sides of an IDT area when viewed in the surface acoustic wave propagation direction.

Each of one end of the first IDT 9a of the first longitudinally coupled resonator surface acoustic wave filter portion 9 and one end of the third IDT 9c thereof is connected to a ground potential. The other end of the first IDT 9a of the first longitudinally coupled resonator surface acoustic wave filter portion 9 is connected to one end of the first IDT 10a of the second longitudinally coupled resonator surface acoustic wave filter portion 10. The other end of the first IDT 10a thereof is connected to a ground potential. In a similar manner, with the one end of the third IDT 9c of the first longitudinally coupled resonator surface acoustic wave filter portion 9 being connected to a ground potential, the other end thereof is connected to one end of the third IDT 10c of the second longitudinally coupled resonator surface acoustic wave filter portion 10. The other end of the third IDT 10c thereof is connected to a ground potential.

As in the connection between the first longitudinally coupled resonator surface acoustic wave filter portion 9 and the second longitudinally coupled resonator surface acoustic wave filter portion 10, the first IDT 11a of the first longitudinally coupled resonator surface acoustic wave filter portion 11 and the first IDT 12a of the second longitudinally coupled resonator surface acoustic wave filter portion 12 are connected to each other. In addition, the third IDT 11c and the third IDT 12c are connected to each other. The other ends of the IDTs 11a, 11c, 12a, and 12c, which are not connected to the other IDTs, are connected to a ground potential.

One end of the second IDT 10b of the second longitudinally coupled resonator surface acoustic wave filter portion 10, which is provided at the approximate center thereof, and one end of the second IDT 12b of the second longitudinally coupled resonator surface acoustic wave filter portion 12, which is provided at the approximate center thereof, are connected in common to the first balanced terminal 7. In addition, the other end of the second IDT 10b of the second longitudinally coupled resonator surface acoustic wave filter portion 10 and the other end of the second IDT 12b of the second longitudinally coupled resonator surface acoustic wave filter portion 12 are connected in common to the second balanced terminal 8.

With such a connection structure, each of the circuit that is defined by the first longitudinally coupled resonator surface acoustic wave filter portion 9 and the second longitudinally coupled resonator surface acoustic wave filter portion 10 that are cascade-connected and the circuit that is made up of the first longitudinally coupled resonator surface acoustic wave filter portion 11 and the second longitudinally coupled resonator surface acoustic wave filter portion 12 that are cascade-connected is a float-balance type surface acoustic wave filter having a balanced/unbalanced conversion function.

Although they are not illustrated in FIG. 1 for simplicity, each of the first longitudinally coupled resonator surface acoustic wave filter portion 9, the second longitudinally coupled resonator surface acoustic wave filter portion 10, the first longitudinally coupled resonator surface acoustic wave filter portion 11, and the second longitudinally coupled resonator surface acoustic wave filter portion 12 is provided with narrow pitch electrode finger portions. The term “narrow pitch electrode finger portion” is defined as a portion that includes, at a regional portion where two IDTs are arranged opposite to each other when viewed in the surface acoustic wave propagation direction with a gap therebetween, at least a portion of electrode fingers facing the gap. In addition, the narrow pitch electrode finger portion means an electrode finger portion whose electrode finger pitch is less, that is, narrower, than that of the remaining electrode finger portions.

As an example of the structure of such a narrow pitch electrode finger portion, an explanation is provided of narrow pitch electrode finger portions of the first IDT 9a, the second IDT 9b, and the third IDT 9c of the first longitudinally coupled resonator surface acoustic wave filter portion 9 while referring to an enlarged view of FIG. 2. Narrow pitch electrode finger portions 9a₁ and 9b₁ are provided at a regional portion where the first IDT 9a and the second IDT 9b are arranged opposite to each other with a gap G therebetween. The narrow pitch electrode finger portion 9a₁ includes a plurality of electrode fingers whose electrode finger pitch is narrower than that of the remaining electrode finger portions of the first IDT 9a. In a similar manner, the second IDT 9b and the third IDT 9c are provided with narrow pitch electrode finger portions 9b₂ and 9c₁, respectively, at a regional portion where the second IDT 9b and the third IDT 9c are provided opposite to each other with another gap G therebetween. Accordingly, the second IDT 9b arranged at the approximate center thereof includes the narrow pitch electrode finger portion 9b₁ provided at one side thereof and the narrow pitch electrode finger portion 9b₂ provided at the other side thereof when viewed in the surface acoustic wave propagation direction. The electrode finger pitch of each of the narrow pitch electrode finger portions 9b₁ and 9b₂ is narrower than that of the remaining electrode finger portions of the second IDT 9b.

Each of the second longitudinally coupled resonator surface acoustic wave filter portion 10, the first longitudinally coupled resonator surface acoustic wave filter portion 11, and the second longitudinally coupled resonator surface acoustic wave filter portion 12 is provided with narrow pitch electrode finger portions having substantially the same structure as described above. It is known in the field of a longitudinally coupled resonator surface acoustic wave filter that it is possible to improve the continuity of a surface acoustic wave propagation path between two IDTs by providing narrow pitch electrode finger portions at a gap-facing region where the two IDTs are provided adjacent to each other. In addition, it is also known in the art that the improved path continuity makes it possible to reduce insertion loss in a surface acoustic wave filter having a balanced/unbalanced conversion function. As in such a conventional structure of a longitudinally coupled resonator surface acoustic wave filter, the narrow pitch electrode finger portions are provided in the present preferred embodiment in order to reduce insertion loss.

In addition, in the present preferred embodiment, the number of electrode fingers of the narrow pitch electrode finger portion of each of the second IDT 9b of the first longitudinally coupled resonator surface acoustic wave filter portion 9 and the second IDT 11b of the first longitudinally coupled resonator surface acoustic wave filter portion 11 is greater than the number of electrode fingers of the narrow pitch electrode finger portion of each of the second IDT 10b of the second longitudinally coupled resonator surface acoustic wave filter portion 10 and the second IDT 12b of the second longitudinally coupled resonator surface acoustic wave filter portion 12. With such a structure, it is possible to increase impedance in the pass band of the transmission-side band pass filter 4 without causing an increase in insertion loss in the reception-side band pass filter 5, which is an example of the second band pass filter that has a relatively high pass band. A detailed explanation is provided below with reference to an example of an experiment.

The design specification of the first longitudinally coupled resonator surface acoustic wave filter portion 9 is as follows:
Let the wavelength thereof be λI, which is determined on the basis of an IDT electrode finger pitch.
Electrode finger cross width in the IDT 9a-9c=about 18.6 λI
The number of the electrode fingers of the IDT 9a, 9c=30
The number of the electrode fingers of the IDT 9b=38

In the above example, three of the thirty electrode fingers thereof define the electrode fingers of the narrow pitch electrode finger portion.

In the above example, the number of the electrode fingers of each of the narrow pitch electrode finger portions provided at both sides thereof is equal to seven. Therefore, the number of the electrode fingers of the IDT 9b excluding both of the narrow pitch electrode finger portions thereof is equal to 24 (38−7−7=24).
The number of the electrode fingers of the reflector 9d, 9e=65
Metallization ratio=about 0.73
Electrode film thickness=about 0.095 λI

The design specifications of the first longitudinally coupled resonator surface acoustic wave filter portion 11 is substantially the same as that of the first longitudinally coupled resonator surface acoustic wave filter portion 9.

The design specification of the second longitudinally coupled resonator surface acoustic wave filter portion 10 is as follows:
Let the wavelength thereof be λI, which is determined on the basis of an IDT electrode finger pitch.
Electrode finger cross width in the IDT 10a-10c=about 18.6 λI
The number of the electrode fingers of the IDT 10a, 10c=30
The number of the electrode fingers of the IDT 10b=38

In the above example, three of the thirty electrode fingers thereof define the electrode fingers of the narrow pitch electrode finger portion.

In the above example, the number of the electrode fingers of each of the narrow pitch electrode finger portions provided at both sides thereof is equal to four. Therefore, the number of the electrode fingers of the IDT 10b excluding both of the narrow pitch electrode finger portions thereof is equal to 30 (38−4−4=30).
The number of the electrode fingers of each reflector=65
Metallization ratio=about 0.73
Electrode film thickness=about 0.095 λI

The design specifications of the second longitudinally coupled resonator surface acoustic wave filter portion 12 is substantially the same as that of the second longitudinally coupled resonator surface acoustic wave filter portion 10.

As explained above, the number of the electrode fingers of each of the narrow pitch electrode finger portions provided at both sides of each of the second IDTs 9b and 11b of the first longitudinally coupled resonator surface acoustic wave filter portions that are connected to the common terminal 3 is seven, which is greater than the number of the electrode fingers of each of the narrow pitch electrode finger portions provided at both sides of each of the second IDTs 10b and 12b of the second longitudinally coupled resonator surface acoustic wave filter portions, that is, four.

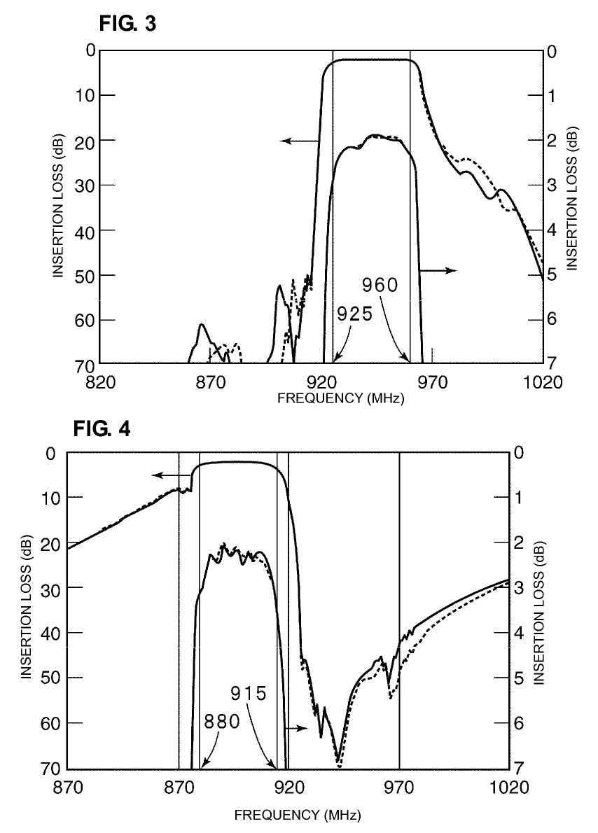

FIG. 3 illustrates the transmission characteristics of the reception-side band pass filter 5 in the duplexer 1 according to the present preferred embodiment. Note that enlarged transmission characteristics are shown together with the transmission characteristics of the reception-side band pass filter 5 in FIG. 3. On the other hand, FIG. 4 illustrates the transmission characteristics of the transmission-side band pass filter 4. Note that enlarged transmission characteristics are shown together with the transmission characteristics of the transmission-side band pass filter 4 in FIG. 4.

A duplexer 1101 according to a comparative example having an electrode structure illustrated in FIG. 6 was prepared for the purpose of comparison. The transmission characteristics of the duplexer 1101 according to the comparative example were measured. The configuration of the duplexer 1101 according to the comparative example is as follows. The configuration of a piezoelectric substrate 1102 of the duplexer 1101 according to the comparative example and the material of electrodes provided on the piezoelectric substrate 1102 are substantially the same as those of the duplexer 1 according to the present preferred embodiment. In addition, the transmission-side band pass filter 4 of the duplexer 1101 according to the comparative example is substantially the same as the transmission-side band pass filter 4 of the duplexer 1 according to the present preferred embodiment. The difference between the duplexer 1101 according to the comparative example and the duplexer 1 according to the present preferred embodiment of the present invention is that, in the configuration of a reception-side band pass filter 1105 of the duplexer 1101, a circuit that includes a first longitudinally coupled resonator surface acoustic wave filter portion 1109 and a second longitudinally coupled resonator surface acoustic wave filter portion 1110 that are cascade-connected and a circuit that includes a first longitudinally coupled resonator surface acoustic wave filter portion 1111 and a second longitudinally coupled resonator surface acoustic wave filter portion 1112 that are cascade-connected are connected in parallel.

Each of the first longitudinally coupled resonator surface acoustic wave filter portions 1109 and 1111 is a three IDT-type longitudinally coupled resonator surface acoustic wave filter. One end of the center IDT 1109b of the first longitudinally coupled resonator surface acoustic wave filter portion 1109 and one end of the center IDT 1111b of the first longitudinally coupled resonator surface acoustic wave filter portion 1111 are connected in common to the common terminal 3, which defines an unbalanced terminal. The first longitudinally coupled resonator surface acoustic wave filter portion 1109 and the second longitudinally coupled resonator surface acoustic wave filter portion 1110 are connected to each other in substantially the same manner as in the connection according to the preferred embodiment of the present invention described above. In addition, the first longitudinally coupled resonator surface acoustic wave filter portion 1111 and the second longitudinally coupled resonator surface acoustic wave filter portion 1112 are connected to each other in substantially the same manner as in the present preferred embodiment.

However, in this comparative example, one end of the second IDT 1110b of the second longitudinally coupled resonator surface acoustic wave filter portion 1110, which is provided at the approximate center thereof, is connected to a ground potential and the other end thereof is connected to the first balanced terminal 7. In addition, one end of the center second IDT 1112b of the other of the two second longitudinally coupled resonator surface acoustic wave filter portions, that is, the second longitudinally coupled resonator surface acoustic wave filter portion 1112, is connected to a ground potential and the other end thereof is connected to the second balanced terminal 8. In order to ensure that the longitudinally coupled resonator surface acoustic wave filter has a balanced/unbalanced conversion function, the IDTs 1110b and 1112b are arranged such that the phase of the transmission characteristics of the second IDT 1112b is reversed with respect to the transmission characteristics of the second IDT 1110b.

Therefore, the reception-side band pass filter 1105 of the duplexer 1101 according to the comparative example is a neutral-point type longitudinally coupled resonator surface acoustic wave filter having a balanced/unbalanced conversion function.

The duplexer 1101 according to the comparative example is designed with the following specifications.

The design specifications of the first longitudinally coupled resonator surface acoustic wave filter portion 1109:
Let the wavelength thereof be λI, which is determined on the basis of an IDT electrode finger pitch.
Electrode finger cross width in the IDT 1109a-1109c=about 33.9 λI
The number of the electrode fingers of the IDT 1109a, 1109c=32
The number of the electrode fingers of the IDT 1109b=28

In the above example, three of the thirty-two electrode fingers thereof define the electrode fingers of the narrow pitch electrode finger portion.

A narrow pitch electrode finger portion that includes three electrode fingers is provided at each of the two sides of the IDT 1109b. Therefore, the number of the electrode fingers of the IDT 1109b excluding both of the narrow pitch electrode finger portions thereof is equal to 22 (28−3−3=22).
The number of the electrode fingers of each reflector=65
Metallization ratio=about 0.73
Electrode film thickness=about 0.095 λI

The design specifications of the first longitudinally coupled resonator surface acoustic wave filter portion 1111 is substantially the same as that of the first longitudinally coupled resonator surface acoustic wave filter portion 1109.

The design specifications of the second longitudinally coupled resonator surface acoustic wave filter portion 1110:
Let the wavelength thereof be λI, which is determined on the basis of an IDT electrode finger pitch.
Electrode finger cross width in the IDT 1110a-1110c=about 33.9 λI
The number of the electrode fingers of the IDT 1110a, 1110c=32
The number of the electrode fingers of the IDT 1110b=44

In the above example, three of the thirty-two electrode fingers thereof define the electrode fingers of the narrow pitch electrode finger portion.

In the above example, the number of the electrode fingers of each of the narrow pitch electrode finger portions provided at both sides thereof is equal to seven. Therefore, the number of the electrode fingers of the IDT 1110b excluding both of the narrow pitch electrode finger portions thereof is equal to 30 (44−7−7=30).
The number of the electrode fingers of each reflector=65
Metallization ratio=about 0.73
Electrode film thickness=about 0.095 λI

The design specifications of the second longitudinally coupled resonator surface acoustic wave filter portion 1112 is substantially the same as that of the second longitudinally coupled resonator surface acoustic wave filter portion 1110 except that, as explained above, the orientation of the IDT 1112b is not the same as the orientation of the IDT 1110b.

As described above, the reception-side band pass filter 1105 of the duplexer 1101, which is prepared as the comparative example, is a neutral-point type longitudinally coupled resonator surface acoustic wave filter having a balanced/unbalanced conversion function. In addition, the number of the electrode fingers of each of the narrow pitch electrode finger portions provided at both sides of each of the second IDTs 1109b and 1111b of the first longitudinally coupled resonator surface acoustic wave filter portions that are connected to the common terminal 3 is less than the number of the electrode fingers of each of the narrow pitch electrode finger portions provided at both sides of each of the second IDT 1110b of the second longitudinally coupled resonator surface acoustic wave filter portion 1110, which is connected to the first balanced terminal 7, and the second IDT 1112b of the second longitudinally coupled resonator surface acoustic wave filter portion 1112, which is connected to the second balanced terminal 8.

In FIGS. 3 and 4, the transmission characteristics of the reception-side band pass filter of the duplexer 1101, which is prepared as the comparative example, and the transmission characteristics of the transmission-side band pass filter thereof are shown respectively, each by a broken line.

As shown in FIG. 3, in the reception-side band pass filter, insertion loss in the pass band and attenuation in the transmission-side band of the present preferred embodiment described above and those of the comparative example are approximately equal to each other. In contrast, as shown in FIG. 4, the transmission characteristics of the transmission-side band pass filter according to the present preferred embodiment has greater steepness at the high pass-band side as compared to those of the comparative example, which results in a reduction in insertion loss.

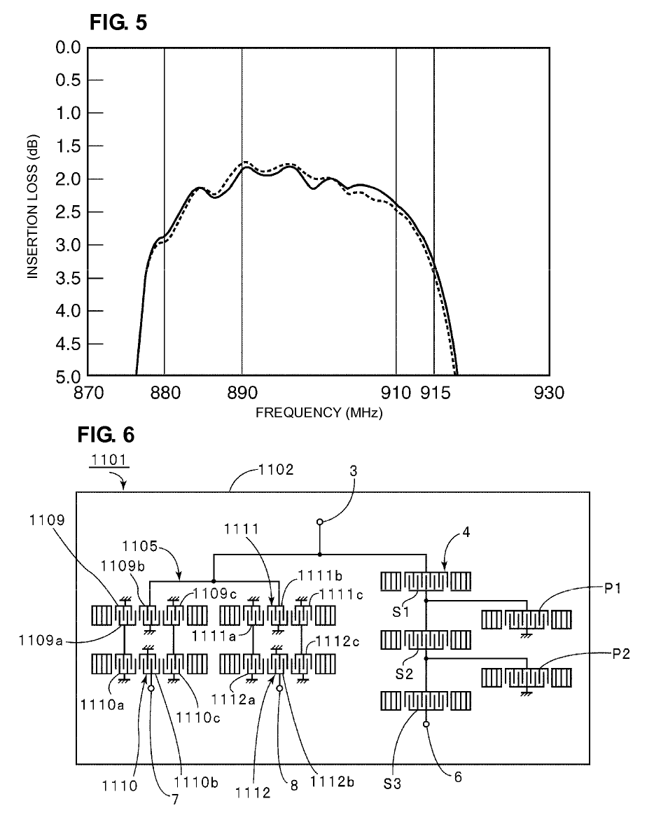

For further clarification, characteristics obtained when loss caused by impedance mismatching in the transmission-side band pass filter is eliminated through calculation are shown in FIG. 5. The solid line of FIG. 5 indicates the results according to the present preferred embodiment. The broken line of FIG. 5 indicates the result according to the comparative example.

The EGSM transmission frequency band ranges from about 880 MHz to about 915 MHz. As shown in FIG. 5, insertion loss is the greatest at about 915 MHz in this transmission frequency band. As indicated by the solid line of FIG. 5, it is understood that the present preferred embodiment improves the insertion loss in the pass band as compared to the comparative example by approximately 0.2 dB.

As explained above, according to the present preferred embodiment, in the reception-side band pass filter, the impedance in the pass band of the transmission-side band pass filter can be increased so as to achieve sufficiently large attenuation in the transmission-side band pass filter. In addition, the insertion loss of the transmission-side band pass filter can be improved. It is conceivable that these advantages are attributable to the following reasons.

In the present preferred embodiment, as described above, the reception-side band pass filter 5 is a float type surface acoustic wave filter having a balanced/unbalanced conversion function. In addition, in the present preferred embodiment, the number of electrode fingers of the narrow pitch electrode finger portion of each of the IDTs 9b and 11b connected to the common terminal 3, which define an unbalanced terminal, is greater than the number of electrode fingers of the narrow pitch electrode finger portion of each of the IDTs 10b and 12b connected to the first balanced terminal 7 and the second balanced terminal 8. Generally, impedance decreases as the number of electrode fingers of a narrow pitch electrode finger portion increases, and impedance increases as the number of electrode fingers of a narrow pitch electrode finger portion decreases. In addition, in a float type filter, if an unbalanced-terminal-side filter has substantially the same design as that of a balanced-terminal-side filter, the ratio of the impedance of a balanced terminal to the impedance of an unbalanced terminal is approximately 1:1. Therefore, in order to ensure that the ratio of the impedance of a balanced terminal to the impedance of an unbalanced terminal is greater than 1:1, or more specifically, in order to ensure that the ratio of the impedance of a balanced terminal to the impedance of an unbalanced terminal is approximately 2:1, as described in the foregoing preferred embodiment, it is possible to achieve impedance matching by making the number of electrode fingers of the narrow pitch electrode finger portion of each of the IDTs 9b and 11b connected to the unbalanced terminal relatively large and by making the number of electrode fingers of the narrow pitch electrode finger portion of each of the IDTs 10b and 12b connected to the first balanced terminal 7 and the second balanced terminal 8 relatively small.

In contrast, in a neutral-point type filter, if an unbalanced-terminal-side filter has substantially the same design as that of a balanced-terminal-side filter, the ratio of the impedance of a balanced terminal to the impedance of an unbalanced terminal is approximately 4:1. Therefore, in order to ensure that the ratio of the impedance of a balanced terminal to the impedance of an unbalanced terminal is approximately 2:1 as described in the comparative example, it is possible to achieve impedance matching by making the number of electrode fingers of the narrow pitch electrode finger portion of each of the IDTs 1109b and 1111b connected to the unbalanced terminal relatively small and by making the number of electrode fingers of the narrow pitch electrode finger portion of each of the IDT 1110b connected to the first balanced terminal 7 and the IDT 1112b connected to the second balanced terminal 8 relatively large.

Therefore, in order to obtain such characteristics that the ratio of the impedance of a balanced terminal to the impedance of an unbalanced terminal is not less than 1:1 but not greater than 4:1, the number of electrode fingers of each of IDTs connected to the common terminal 3, which defines an unbalanced terminal, including the number of electrode fingers of the narrow pitch electrode finger portions thereof in the configuration of the float type filter is greater than that of the neutral-point type filter. Therefore, the float type filter has a smaller influence on the transmission-side band pass filter as compared to that of the neutral-point type filter. Thus, the foregoing preferred embodiment of the present invention provides improved insertion loss in the transmission-side band pass filter, as compared to the comparative example.

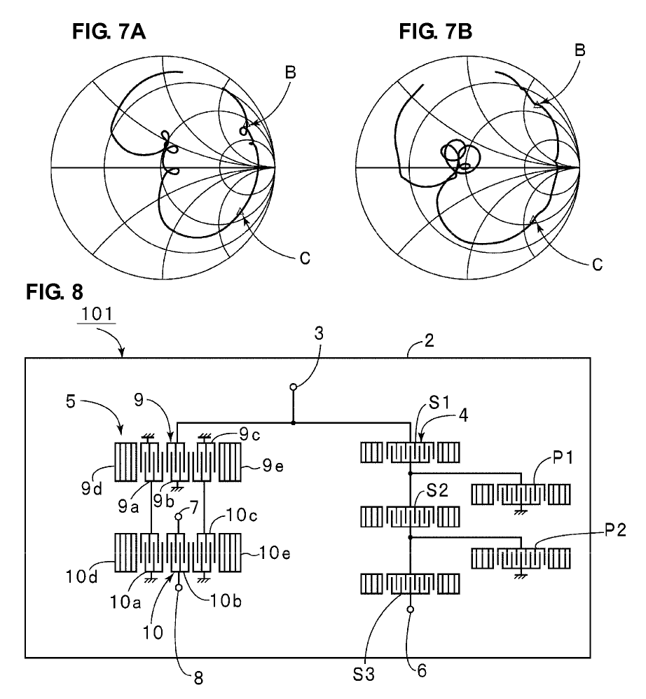

FIGS. 7A and 7B are impedance Smith charts that illustrate the impedance in the common terminal 3 obtained when the transmission-side band pass filter is removed in the present preferred embodiment and in the comparative example, respectively. In FIGS. 7A and 7B, a marker B indicates the impedance at about 880 MHz, and a marker C indicates impedance at about 915 MHz. That is, the markers B and C indicate the impedance of the reception-side band pass filter at the lowest frequency of the pass band of the transmission-side band pass filter and at the highest frequency thereof, respectively.

When the impedance of the reception-side band pass filter as a single unit is considered, the influence on the transmission-side band pass filter can be reduced as the impedance of the reception-side band pass filter in the pass band of the transmission-side band pass filter moves to a relatively outer side of a Smith chart where a resistance component is relatively large. As shown in FIGS. 7A and 7B, in the reception-side band pass filter according to the present preferred embodiment, which is the float type shown in FIG. 7A, since impedance in the transmission-side pass band is shifted to a relatively outer side of the Smith chart so that a resistance component of the impedance in the pass band of the transmission-side band pass filter is relatively large, an influence on the transmission-side band pass filter is reduced as compared to that of the neutral-point type filter.

In the present preferred embodiment, the transmission-side band pass filter 4 is preferably a surface acoustic wave filter having a ladder-type circuit configuration, whereas the reception-side band pass filter 5 includes a circuit that includes the first longitudinally coupled resonator surface acoustic wave filter portion 9 and the second longitudinally coupled resonator surface acoustic wave filter portion 10 that are cascade-connected and a circuit that includes the first longitudinally coupled resonator surface acoustic wave filter portion 11 and the second longitudinally coupled resonator surface acoustic wave filter portion 12 that are cascade-connected are connected in parallel. In a duplexer according to a preferred embodiment of the present invention, the circuit configuration of the first band pass filter that is defined by the transmission-side band pass filter explained above and/or the circuit configuration of the second band pass filter that is defined by the reception-side band pass filter explained above may be arbitrarily modified.

That is, the transmission-side band pass filter 4 is not limited to a surface acoustic wave filter having a ladder-type circuit configuration. The transmission-side band pass filter 4 may preferably be a longitudinally coupled resonator surface acoustic wave filter. That is, the circuit configuration of the transmission-side band pass filter 4, which is an example of the first band pass filter, is not limited to the illustrated example.

In the preferred embodiment of the present invention described above, the reception-side band pass filter 5 has a configuration in which a circuit that includes the first longitudinally coupled resonator surface acoustic wave filter portion 9 and the second longitudinally coupled resonator surface acoustic wave filter portion 10 that are cascade-connected and a circuit that includes the first longitudinally coupled resonator surface acoustic wave filter portion 11 and the second longitudinally coupled resonator surface acoustic wave filter portion 12 that are cascade-connected are connected in parallel. However, as illustrated in FIG. 8, a duplexer 101 may preferably include a single circuit that includes the first longitudinally coupled resonator surface acoustic wave filter portion 9 and the second longitudinally coupled resonator surface acoustic wave filter portion 10 that are cascade-connected.

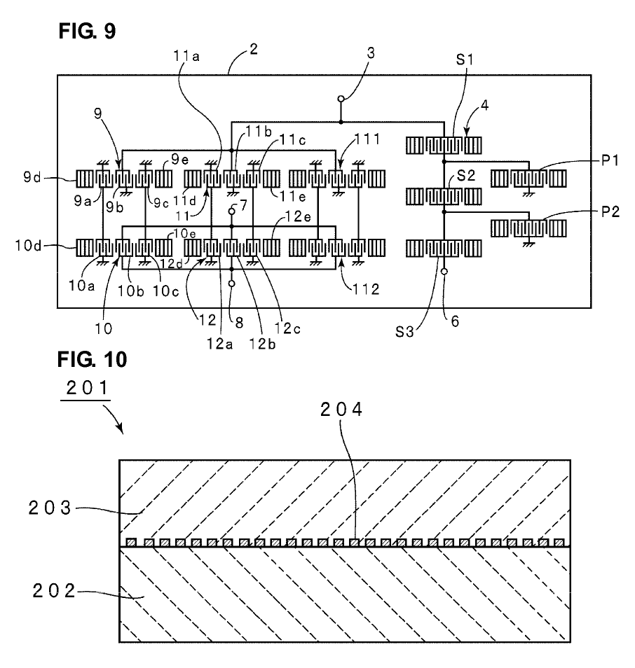

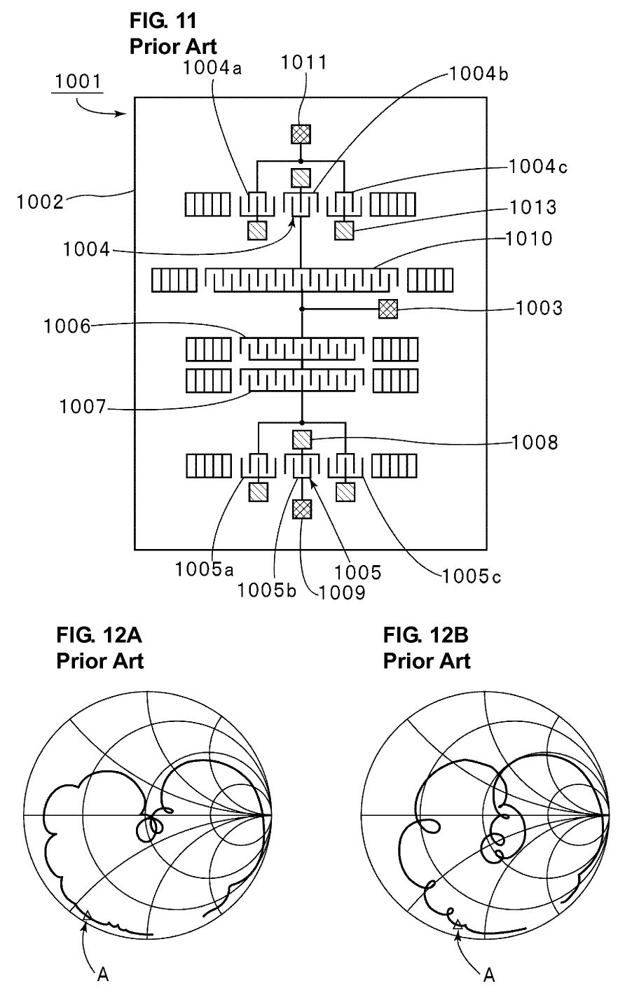

As another modified example shown in FIG. 9, a circuit that includes another pair of a first longitudinally coupled resonator surface acoustic wave filter portion 111 and a second longitudinally coupled resonator surface acoustic wave filter portion 112 that are cascade-connected, the circuit that includes the first longitudinally coupled resonator surface acoustic wave filter portion 9 and the second longitudinally coupled resonator surface acoustic wave filter portion 10 that are cascade-connected, and the circuit that includes the first longitudinally coupled resonator surface acoustic wave filter portion 11 and the second longitudinally coupled resonator surface acoustic wave filter portion 12 that are cascade-connected may be connected in parallel. As described above, the number of circuits, each of which includes a first longitudinally coupled resonator surface acoustic wave filter portion and a second longitudinally coupled resonator surface acoustic wave filter portion that are cascade-connected, may be any arbitrary number of two or greater, for example, where respective ends of these circuits are connected in common to the common terminal 3. That is, the number of circuits that are connected in parallel is not specifically restricted.

Although the second band pass filter according to a preferred embodiment of the present invention is preferably provided in the duplexer 1 in the preferred embodiment described above, the scope of the present invention is not limited thereto. That is, the present invention is applicable to a second band pass filter for various uses that is provided in various types of a device that includes a first band pass filter and a second band pass filter that have pass bands that are different from each other, wherein one end of the first band pass filter and one end of the second band pass filter are connected in common, and the second band pass filter has a balanced/unbalanced conversion function.

Although a surface acoustic wave filter apparatus is described as an example in the preferred embodiments of the present invention described above and the modified examples thereof, the present invention is also applicable to a boundary acoustic wave filter apparatus that utilizes a boundary acoustic wave instead of a surface acoustic wave. Specifically, in the structure of a boundary acoustic wave filter apparatus 201 that is schematically illustrated in a front-elevation sectional view of FIG. 10, a dielectric layer 203 is provided on a piezoelectric substrate 202, which is made of a piezoelectric material. An electrode structure 204 including IDTs is provided on a boundary surface between the piezoelectric substrate 202 and the dielectric 203. The electrode structure according to the preferred embodiments of the present invention described above is preferably provided as the electrode structure 204. In this manner, it is possible to provide a boundary acoustic wave filter apparatus according to a preferred embodiment of the present invention.

While preferred embodiments of the present invention have been described above, it is to be understood that variations and modifications will be apparent to those skilled in the art without departing the scope and spirit of the present invention. The scope of the present invention, therefore, is to be determined solely by the following claims.

What is claimed is:

1. An acoustic wave filter apparatus having a balanced/unbalanced conversion function and defining a second band pass filter of an acoustic wave filter device that includes a first band pass filter that has a pass band at a relatively low frequency side and the second band pass filter that has a pass band at a relatively high frequency side, one end of the first band pass filter and one end of the second band pass filter being connected to a common terminal, the acoustic wave filter apparatus comprising:
a piezoelectric substrate; and
a first longitudinally coupled resonator acoustic wave filter portion and a second longitudinally coupled resonator acoustic wave filter portion provided on the piezoelectric substrate; wherein
each of the first longitudinally coupled resonator acoustic wave filter portion and the second longitudinally coupled resonator acoustic wave filter portion includes a first IDT, a second IDT, and a third IDT arranged in sequence along a propagation direction of an acoustic wave;
one end of the first IDT of the first longitudinally coupled resonator acoustic wave filter portion and one end of the first IDT of the second longitudinally coupled resonator acoustic wave filter portion are connected to each other, and one end of the third IDT of the first longitudinally coupled resonator acoustic wave filter portion and one end of the third IDT of the second longitudinally coupled resonator acoustic wave filter portion are connected to each other so that the first longitudinally coupled resonator acoustic wave filter portion and the second longitudinally coupled resonator acoustic wave filter portion are cascade-connected;
one end of the second IDT of the first longitudinally coupled resonator acoustic wave filter portion is connected to the common terminal;
one end of the second IDT of the second longitudinally coupled resonator acoustic wave filter portion is connected to a first balanced terminal and the other end of the second IDT of the second longitudinally coupled resonator acoustic wave filter portion is connected to a second balanced terminal;
each of the first longitudinally coupled resonator acoustic wave filter portion and the second longitudinally coupled resonator acoustic wave filter portion includes a narrow pitch electrode finger portion that is provided at a gap-facing portion in a pair of the first, second, and third IDTs that are arranged adjacent to each other with a gap therebetween when viewed in the acoustic wave propagation direction;
a pitch of electrode fingers of the narrow pitch electrode finger portion is less than a pitch of electrode fingers of an IDT portion excluding the narrow pitch electrode finger portion; and
the number of the electrode fingers of the narrow pitch electrode finger portion of the second IDT of the first longitudinally coupled resonator acoustic wave filter portion is greater than the number of the electrode fingers of the narrow pitch electrode finger portion of the second IDT of the second longitudinally coupled resonator acoustic wave filter portion.

2. An acoustic wave filter apparatus comprising:
a plurality of acoustic wave filter apparatuses according to claim 1; wherein
the plurality of acoustic wave filter apparatuses are connected in parallel.

3. An acoustic wave filter apparatus according to claim 1, wherein a surface acoustic wave is used as the acoustic wave so that the acoustic wave filter apparatus defines a surface acoustic wave filter apparatus.

4. An acoustic wave filter apparatus according to claim 1, wherein a boundary acoustic wave is used as the acoustic wave so that the acoustic wave filter apparatus defines a boundary acoustic wave filter apparatus.

5. A duplexer comprising:
a first band pass filter having a relatively low pass band; and
a second band pass filter having a relatively high pass band; wherein
one end of the first band pass filter and one end of the second band pass filter are connected to a common terminal; and
the second band pass filter is an acoustic wave filter apparatus according to claim 1.
